(19) United States
(12) Patent Application Publication
(10) Pub. No.: US 2010/0308925 A1
(43) Pub. Date: Dec. 9, 2010

(54) Method of producing micromachined air-cavity resonator, micromachined air-cavity resonator, band-pass filter and oscillator using the method

(75) Inventors: Sang Sub Song, Seoul (KR); Kwang Seok Seo, Seoul (KR)

Correspondence Address: OHLANDT, GREELEY, RUGGIERO & PERLE, LLP, ONE LANDMARK SQUARE, 10TH FLOOR, STAMFORD, CT, 06901, US

(73) Assignee: Seoul National University Industry Foundation

(21) Appl. No.: 12/456,369

(22) Filed: Jun. 16, 2009

(30) Foreign Application Priority Data
Jun. 9, 2009 (KR) 10-2009-0050955

(51) Int. Cl. H03B 7/12; H01P 7/06; H01L 21/50; H01L 21/311

(52) U.S. Cl. 331/96; 333/230; 333/227; 438/108; 438/694; 257/E21.499; 257/E21.249

(57) ABSTRACT

A micromachined air-cavity resonator, a method for fabricating the micromachined air-cavity resonator, and a band-pass filter and an oscillator using the same are provided. In particular, a micromachined air-cavity resonator including a current probe fabricated together when the air-cavity resonator is fabricated, and a groove structure for rejecting detuning effect when an external circuit of a package substrate is coupled to the current probe, a millimeter-wave band-pass filter using the same, and a millimeter-wave oscillator using the same are provided. The micromachined air-cavity resonator includes a cavity structure which comprises a current probe simultaneously formed through a fabrication process, and a groove structure; and a package substrate integrated with the cavity structure. Thus, the micromachined air-cavity resonator can be easily fabricated by etching a silicon substrate and easily integrated to the package substrate using the flip-chip bonding.

### PRIORITY

This application claims the benefit under 35 U.S.C. §119(a) to a Korean patent application filed in the Korean Intellectual Property Office on Jun. 9, 2009 and assigned Serial No. 10-2009-0050955, the entire disclosure of which is hereby incorporated by reference.

### BACKGROUND OF THE INVENTION

1. Field of the Invention

The present invention relates generally to a micromachined air-cavity resonator, a method for fabricating the micromachined air-cavity resonator, and a band-pass filter and an oscillator using the same. The micromachined air-cavity resonator, the band-pass filter, and the oscillator of the present invention are suitable for millimeter-wave applications.

2. Description of the Related Art

Conventional millimeter-wave resonators having a high Q value are fabricated using a metallic waveguide structure or a dielectric puck. However, the conventional millimeter-wave resonators are subject to a heavy weight, a high fabrication cost, and a troublesome integration on a package substrate.

To replace the conventional millimeter-wave resonator, a low-cost micromachined air-cavity resonator using a bulk micromachining process of silicon is developed to exhibit good performances up to the millimeter-wave frequencies without a dielectric loss. Yet, since this micromachined air-cavity resonator makes use of a typical waveguide input/output interface, it is difficult to integrate on the package substrate together with integrated passive components.

To address the waveguide input/output interface problem, a coupling probe using a metalized pillar was suggested to integrate a micromachined rectangular waveguide on the package substrate (Y, Li, B. Pan, C. Lugo, M. Tentzeris, and J. Papapolymerou, “Design and characterization of a W-band micromachined cavity filter including a novel integrated transition from CPW feeing lines”, IEEE Trans. Microw. Theory Tech., vol. 55, pp. 2902-2910, December 2007), but requires the complicated processes such as silicon dry-etching, stacking, and fabrication of the metalized copolymer pillars.

In recent, a simple surface micromachining polymer-core-conductor approach was developed to integrate the cavity resonator on the package substrate with a low cost. This approach couples the resonator and the external circuit using current probes (B. Pan, Y, Li, M. M. Tentzeris, and J. Papapolymerou, “Surface micromachining polymer-core-conductor approach for high-performance millimeter-wave air-cavity filters integration”, IEEE Trans. Microw. Theory Tech. vol. 56 pp. 959-970, April 2008). Disadvantageously, the polymer-core-conductor using a thick photo-definable polymer SU-8 cannot endure the high temperature and the high pressure. While the air-cavity resonator is integrated to the package substrate by forming the current probe and the wall of the air-cavity resonator on the package substrate, the structure of the probe and the center of the wall, which make use of the photoresist (PR), are susceptible to the heat and the pressure. In addition, the fabrication needs to be conducted on the package substrate.

### SUMMARY OF THE INVENTION

An aspect of the present invention is to address at least the above mentioned problems and/or disadvantages and to provide at least the advantages described below. Accordingly, an aspect of the present invention is to provide a micromachined air-cavity resonator which is easily manufactured by fabricating a semiconductor substrate such as silicon substrate or GaAs substrate, or a glass substrate, and easily integrated onto a package substrate using flip-chip bonding, metal bonding, and epoxy bonding so as to integrate the air-cavity resonator to the package substrate with a low cost.

Another aspect of the present invention is to provide a micromachined air-cavity resonator formed to include a groove structure for rejecting detuning effect when an external circuit of a package substrate is coupled to a current probe, and the current probe fabricated together when the air-cavity resonator is fabricated.

Yet another aspect of the present invention is to provide a micromachined air-cavity resonator using a silicon pillar which is fabricated together with an air-cavity structure through a deep Reactive Ion Etching (RIE) to form the air-cavity structure, as a current probe for coupling the cavity with an external circuit, without additional process for fabricating the current probe.

Still another aspect of the present invention is to provide a novel fabrication method of an air-cavity resonator structure including metalized silicon pillars.

A further aspect of the present invention is to provide a cavity filter with a low insertion loss and an oscillator with a low phase noise as millimeter-wave applications of the air-cavity resonator.

A further aspect of the present invention is to provide a millimeter-wave wireless front-end module of a low cost and a high efficiency using the air-cavity resonator.

According to one aspect of the present invention, a micromachined air-cavity resonator includes a cavity structure which comprises a current probe simultaneously formed through a fabrication process, and a groove structure; and a package substrate integrated with the cavity structure.

At least one groove structure may be formed to get rid of detuning effect an external circuit and the current probe are interconnected, and at least one current probe may be formed in a pillar shape or a wall shape.

An inside of the cavity structure comprising the current prove and the groove structure may be metallically plated.

The micromachined air-cavity resonator may further include a thin-film microstrip or a Coplanar Waveguide (CPW) formed to flip-chip bond with the current probe, for functioning as input and output ports between the cavity structure and the external circuit.

The cavity structure may be in the form of a rectangle or a cylinder.

The fabrication process may be an etching process on a silicon plate, a GaAs substrate, or a glass substrate.

The cavity structure may be integrated onto the package substrate through flip-chip bonding, metal bonding, or epoxy bonding.

A band-pass filter may be constituted with a coupled body of a micromachined air-cavity resonator and integrated to comprise at least one micromachined air-cavity resonator.

According to another aspect of the present invention, an oscillator includes a micromachined air-cavity resonator; a gain block; and a directional coupler. The micromachined air-cavity resonator may be used as a parallel-feedback element.

According to yet another aspect of the present invention, a fabrication method of a micromachined air-cavity resonator includes patterning a silicon dioxide film on a silicon substrate; forming a cavity structure by etching the silicon substrate using the silicon dioxide film as a mask; metallically plating a surface of the etched silicon substrate; and mounting the metal plated cavity structure onto the package substrate.

The forming of the cavity structure by etching the silicon substrate may fabricate the cavity structure to comprise at least one groove structure in a sidewall and at least one silicon pillar current probe within the cavity structure.

The mounting of the cavity structure onto the package substrate may flip-chip bonds the cavity structure and the package substrate.

The etching may be carried out using a deep Reactive Ion Etching (RIE) process or a wet-etching process.

The silicon dioxide film may be deposed in a depth of 2 μm, the silicon substrate may be dry-etched with the deep RIE using a Bosch process until a depth of 230 μm is achieved, the metal plating may be performed by sputtering Ti/Au seed metal layers and electroplating Au in the depth of 5 μm, and the mounting of the metal plated cavity structure onto the package substrate may be a flip-chip bonding using Au/Sn flip-chip bumps.

According to still another aspect of the present invention, a band-pass filter fabricated by integrating a micromachined air-cavity resonator fabricated according to the above method.

According to a further aspect of the present invention, an oscillator which employs a micromachined air-cavity resonator fabricated according to the above method, as a feedback element.

Other aspects, advantages, and salient features of the invention will become apparent to those skilled in the art from the following detailed description, which, taken in conjunction with the annexed drawings, discloses exemplary embodiments of the invention.

### BRIEF DESCRIPTION OF THE DRAWINGS

The above and other aspects, features and advantages of certain exemplary embodiments the present invention will become more apparent from the following detailed description taken in conjunction with the accompanying drawings, in which:

FIG. 1 depicts a geometric structure of an air-cavity resonator including a silicon current probe according to an exemplary embodiment of the present invention;

FIG. 2 is a Scanning Electron Microscope (SEM) photograph of the current probe and a side wall of the air-cavity resonator according to an exemplary embodiment of the present invention;

FIG. 3 is an SEM photograph of a cavity structure of the air-cavity resonator of FIG. 1;

FIG. 4 is a microphotograph of a thin-film substrate forming a package substrate of the air-cavity resonator of FIG. 1;

FIGS. 5A through 5F show changes of an external Q value based on a size and a position of the current probe;

FIG. 6 is a graph showing an S-parameter of 94 Hz air-cavity resonator of FIGS. 3 and 4 based on a current probe tip;

FIG. 7 depicts a fabrication method of the air-cavity resonator according to an exemplary embodiment of the present invention;

FIG. 8 depicts a band-pass filter integrated to the package substrate using the air-cavity resonator structure according to an exemplary embodiment of the present invention;

FIG. 9 is an SEM photograph of the band-pass filter air-cavity resonator structure according to an exemplary embodiment of the present invention;

FIG. 10 is a circuit diagram of a CMOS oscillator using the air-cavity resonator structure according to an exemplary embodiment of the present invention; and

FIG. 11 is a diagram of the air-cavity resonator structure applicable to the oscillator structure of FIG. 10.

Throughout the drawings, like reference numerals will be understood to refer to like parts, components and structures.

### DETAILED DESCRIPTION OF EXEMPLARY EMBODIMENTS

The following description with reference to the accompanying drawings is provided to assist in a comprehensive understanding of exemplary embodiments of the present invention as defined by the claims and their equivalents. It includes various specific details to assist in that understanding but these are to be regarded as merely exemplary. Accordingly, those of ordinary skill in the art will recognize that various changes and modifications of the embodiments described herein can be made without departing from the scope and spirit of the invention. Also, descriptions of well-known functions and constructions are omitted for clarity and conciseness.

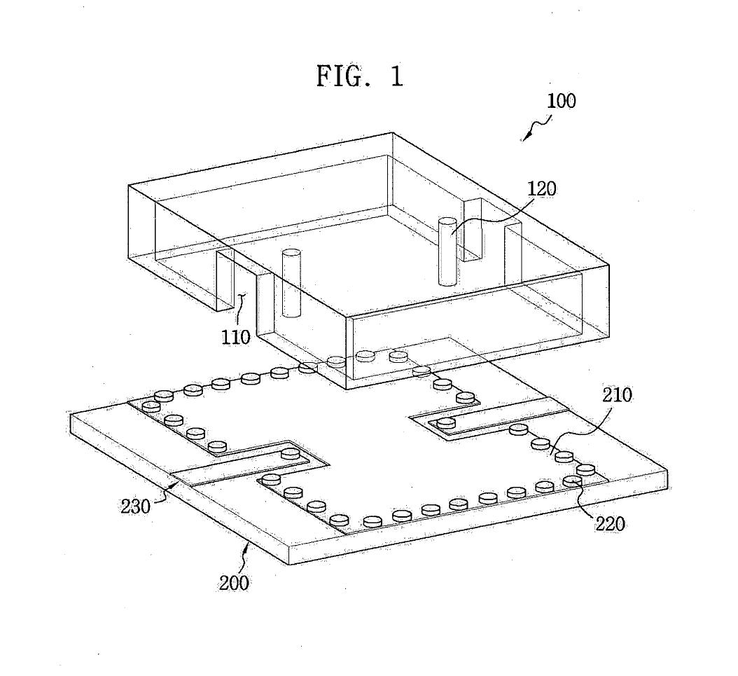

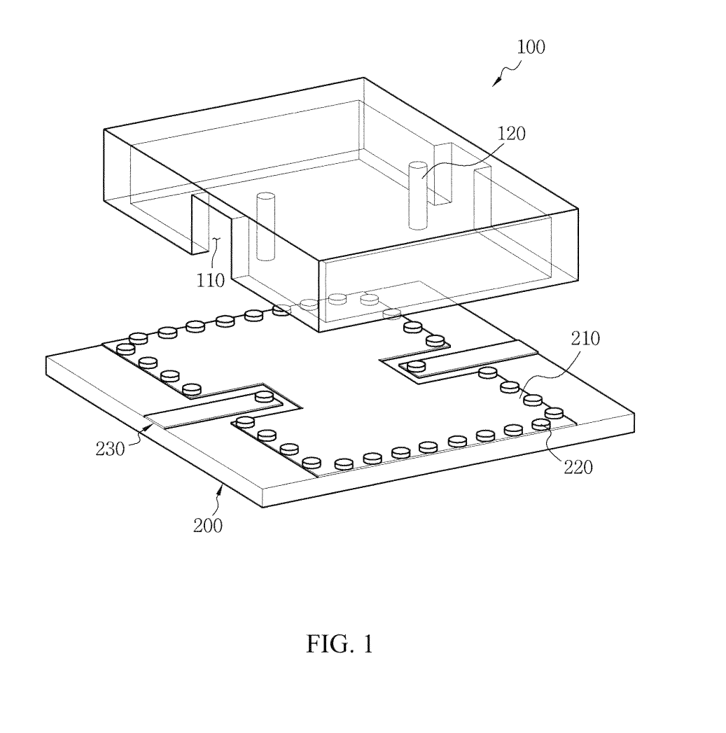

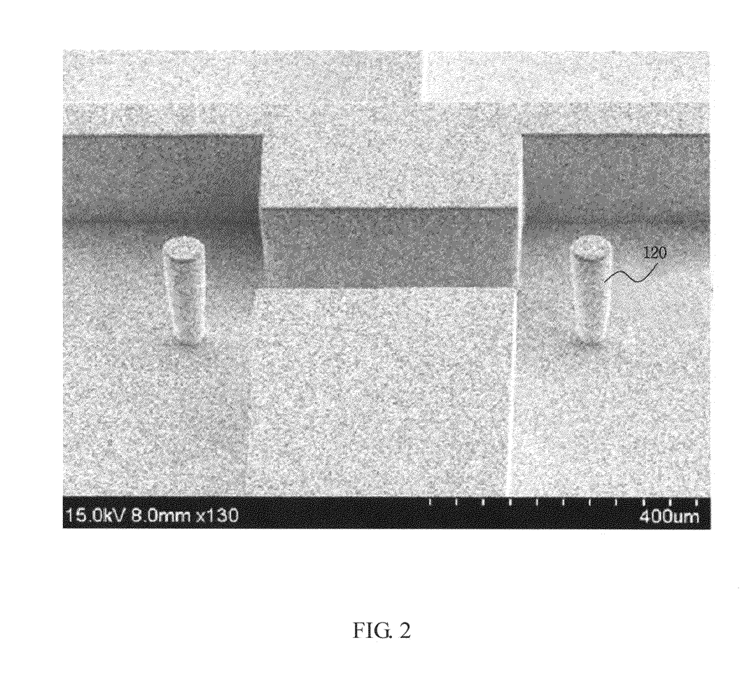

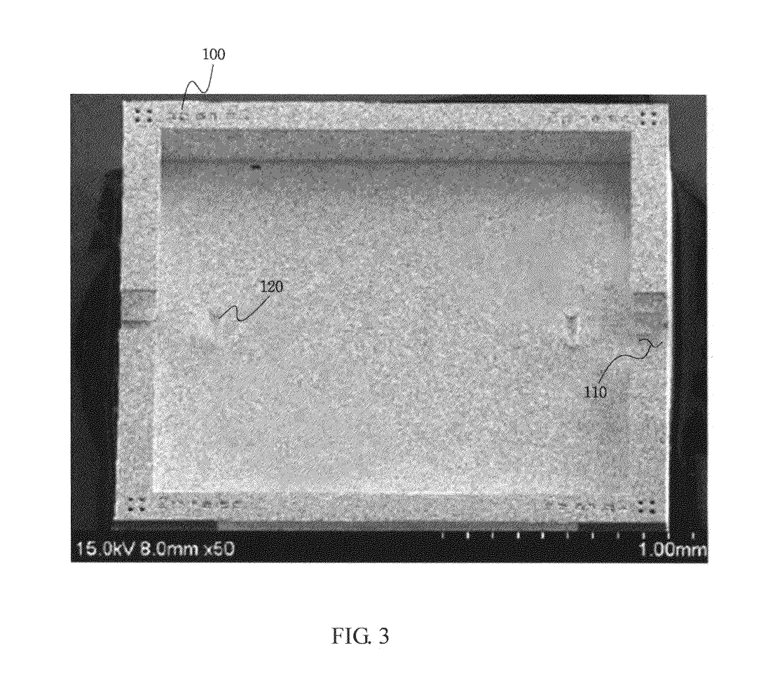

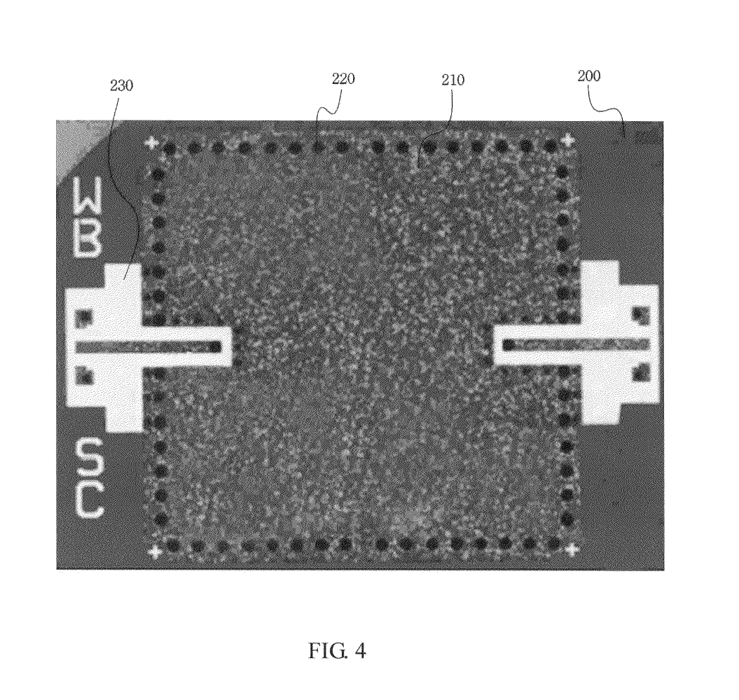

FIG. 1 depicts a geometric structure of an air-cavity resonator including a silicon current probe according to an exemplary embodiment of the present invention, FIG. 2 is a Scanning Electron Microscope (SEM) photograph of the current probe 120 and a side wall of a cavity structure, FIG. 3 is an SEM photograph of the cavity structure of the air-cavity resonator of FIG. 1, and FIG. 4 is a microphotograph of a thin-film substrate forming a package substrate of the air-cavity resonator of FIG. 1.

Exemplary embodiments of the present invention provide a structure and operations of the air-cavity resonator by referring to the attached drawings.

The air-cavity resonator is fabricated by flip-chip mounting a silicon cavity structure 100 formed through a silicon etching process, onto a package substrate 200. Inside the silicon cavity structure 100, silicon pillars which function as current probes 120 are disposed. A groove structure 110 is formed in the sidewall. The cavity structure 100 including the groove structure 110 and the current probe 120 is enclosed with a metal plane of a thin-film substrate 210 used as the package substrate 200.

Unlike conventional polymer pillars formed on the package substrate, the cavity structure 100 including the current probe 120 of FIG. 1 simultaneously fabricates the current probe 120 and the cavity structure 100 using a silicon etching process using a deep Reactive Ion Etching (RIE) and a metal plating process.

Since the micromachined air-cavity structure 100 is flip-chip mounted on the package substrate 200 using a plurality of flip-chip bumps 220, it guarantees the mechanical stability of the micromachined air-cavity structure 100. A radiation loss due to a gap between the cavity and the package substrate can be neglected because a height and a pitch of the flip-chip bump 220 are small.

As configured above, coupling between the air-cavity resonator including the cavity structure 100 and an external circuit 230 on the package substrate 200 can be achieved with the current probes 120, which provides a minimal package substrate effect and a strongly-coupled resonator condition.

To couple the current probe 120 and the package substrate 200, the thin-film substrate 210 including the flip-chip coupling structure by means of the flip-chip bumps 220 is used as the package substrate 200. Input/Output (I/O) feeding lines between the cavity structure 100 and the external circuit 230 employ thin-film microstrip lines or Coplanar Waveguide (CPW) transmission lines.

The groove structure 110 is provided to avoid an unwanted detuning effect in the thin-film microstrip I/O connections between the cavity structure 100 and the external circuit 230. The current probe 120 connected to the thin-film microstrip line excites the cavity using a magnetic coupling.

Herein, the thin-film substrate 210 is formed of a benzocyclobutene (BCB) dielectric and a Au metal thin-film layer alternatively deposited on the substrate. The upper side of the thin-film substrate 210 includes Si bumps and ground bumps for coupling with the current probes 120. For example, embedded passives such as NiCr resistors (i.e., intrinsic resistors) with a sheet resistance of 20 Ω/square or millimeter-wave broadside couplers are formed between BCB layers of the thin-film substrate.

In another embodiment of the present invention, the cavity structure 100 can be fabricated using a different semiconductor substrate such as GaAs substrate, or a glass substrate instead of the silicon substrate, and the integration of the cavity structure 100 onto the package substrate 200 can employ various methods such as metal bonding or epoxy bonding.

While the dry etching using the RIE is adopted in this embodiment, the wet etching using KOH or TMAH solution may be used to fabricate the current probe 120 and the cavity structure 100 at the same time.

The current probe 120 fabricated as above can be formed in a wall shape such that the rectangular pillars form the wall, besides the various pillar shapes. The cavity structure 100 can be formed in a cylindrical shape, besides the rectangle. In this case, one or more current probes 120 are formed in the rectangular or cylindrical cavity structure 100, and one or more groove structures 110 are formed in the sidewall of the rectangular or cylindrical cavity structure 100.

In the design phase of the air-cavity resonator, the sidewalls with the negative-sloped profile should be taken into account in the cavity structure 100—because the negative-sloped profile affects a resonant frequency of the air-cavity resonator.

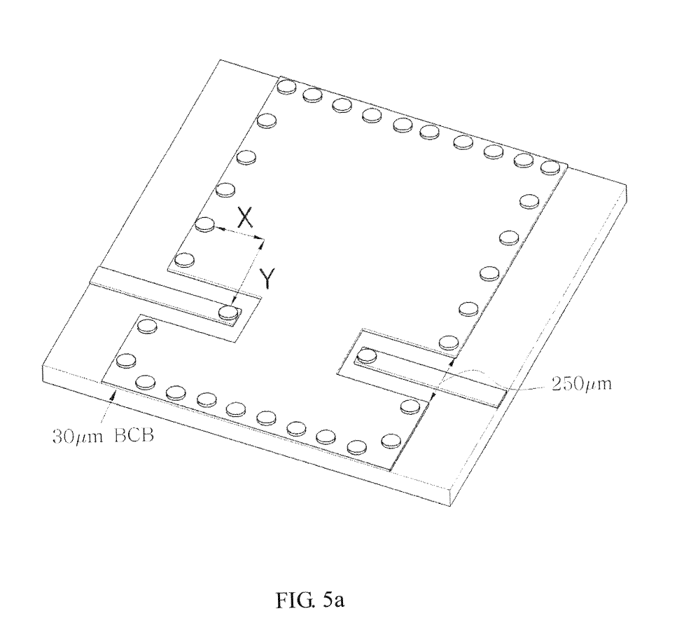

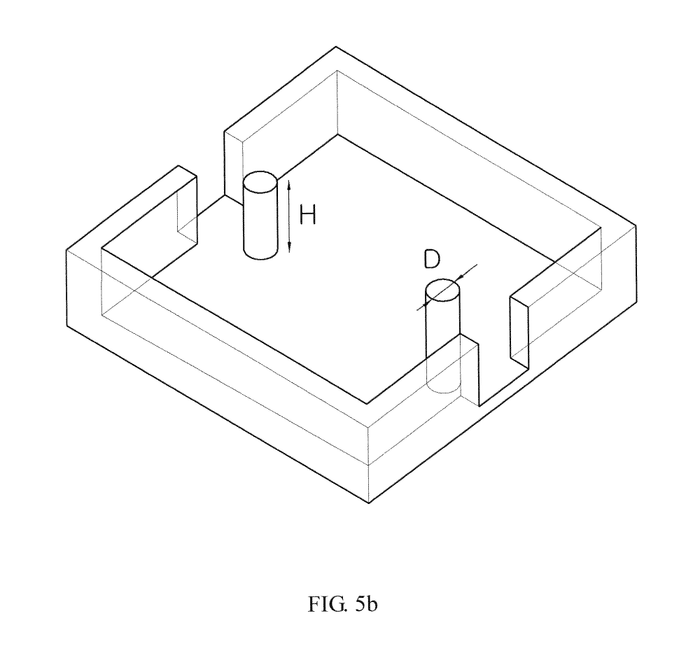

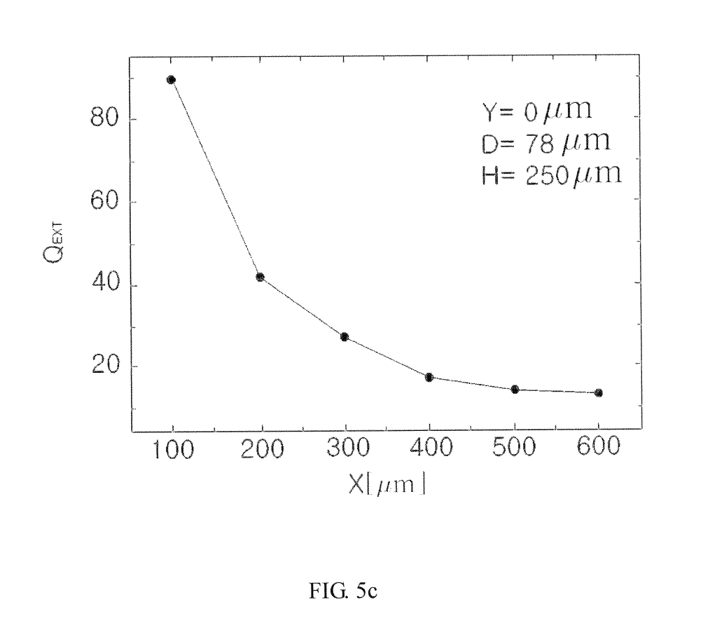

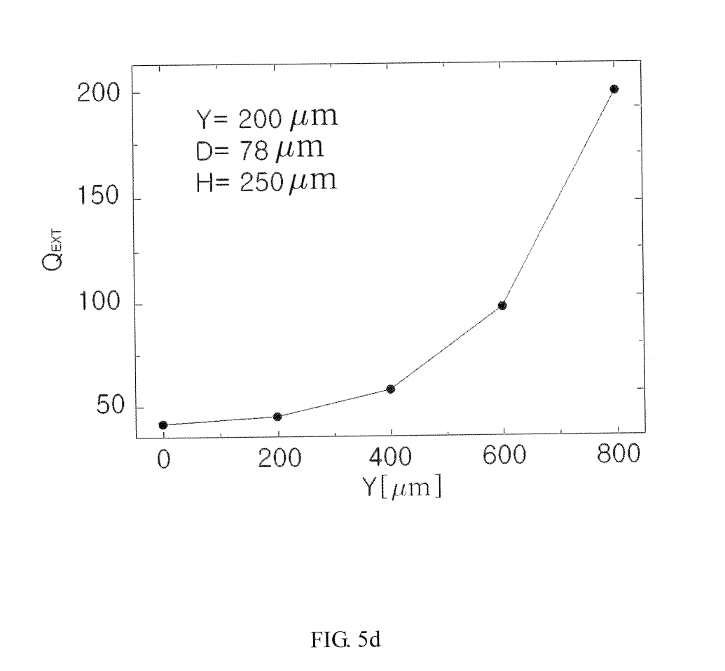

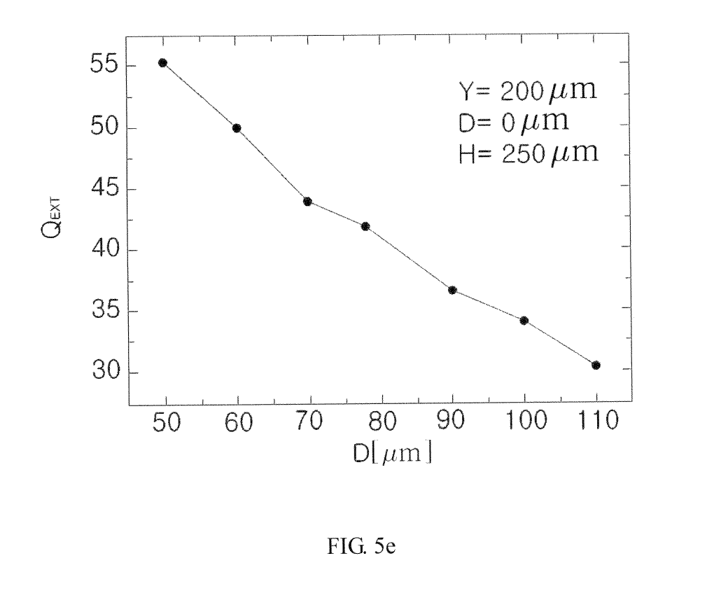

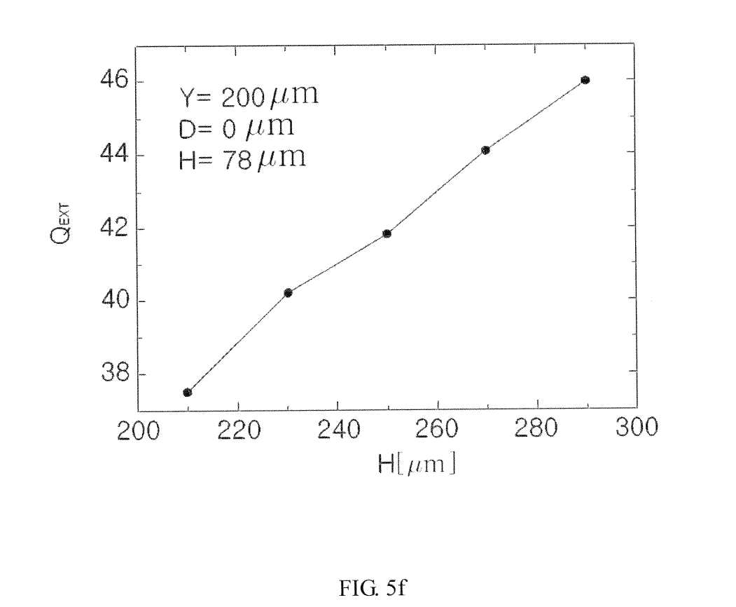

Particularly, a shape and a position of the current prove 120, which can affect an external coupling level, should be considered in the design as well. In this regard, FIGS. 5A through 5F show changes of an external Q value based on the size and the position of the current probe. FIG. 5A shows the positions X and Y of the current probe in the package substrate, and FIG. 5B shows the size of the current probe; that is, a diameter D and a height H. Referring to FIGS. 5C through 5F, as the current probe moves from the center of the cavity to the corner and the edge, the external coupling decreases. As the height H of the current probe increases or the diameter D of the current probe decreases, the external coupling also reduces.

The resonant frequency also changes depending on the position and the size of the current probe. Accordingly, it is necessary to adjust the size of the cavity so as to compensate the frequency shift.

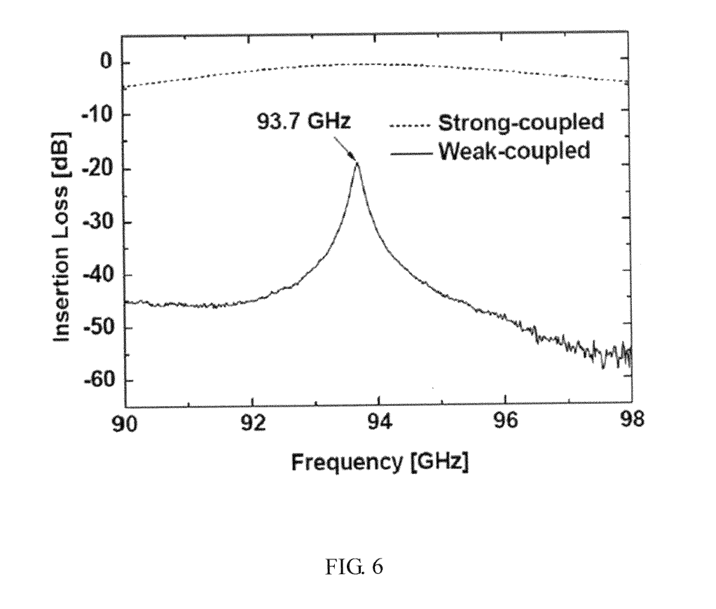

FIG. 6 is a graph showing an S-parameter of 94 Hz air-cavity resonator of FIGS. 3 and 4, which is measured based on a current probe tip.

In the weak-coupled resonator condition with a coupling of 19.45 dB, the loaded Q Q_{L} is 624 and the resonant frequency is 93.7 GHz. A small frequency shift of 0.32% from the center frequency is attributed to a discrepancy of the plating metal thickness between the sidewall and the plane. By considering the loss 0.15 dB in the thin-film microstrip feeding lines, the unladed Q Q_{U} of the resonator is calculated to be 700. Under the strong-coupled resonator condition with the external coupling Q_{EXT} of 27, the air-cavity yields the coupling of 0.6 dB.

The above-stated results verify that the air-cavity resonator is applicable to millimeter-wave applications such as band-pass filters and fundamental oscillators.

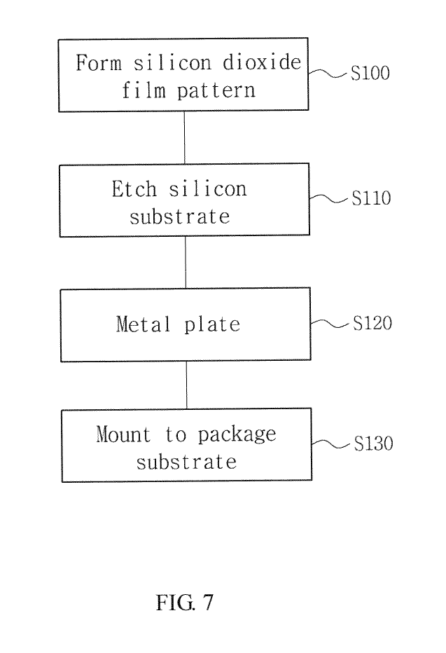

Now, a fabrication method of the air-cavity resonator is illustrated according to an exemplary embodiment of the present invention by referring to FIG. 7.

In the fabrication of the air-cavity structure, to form a silicon oxide film mask pattern, a silicon dioxide is deposited on the silicon substrate in the depth of 2 μm and patterned as an etch mask (S100).

In the etching step of the silicon substrate, the silicon substrate is dry-etched using a deep RIE process with the Bosch process until the depth of 230 μm is achieved (S110). As mentioned earlier, the wet etching using the KOH or TMAH solution can be applied.

In the metal plating step, Ti/Au seed metal layers are sputtered and Au is electroplated with the thickness of 5 μm (S120).

The silicon etching process using the deep RIE technique may yield the negative-sloped profile in the large etching area. This phenomenon can be corrected by adjusting the etching conditions to lower an etch rate.

In the package substrate mounting step, the fabricated cavity structure is flip-chip mounted on the thin-film substrate using the Au/Sn flip-chip bumps (S130). The height of the Au/Sn bumps is about 20 μm after the flip-chip bonding.

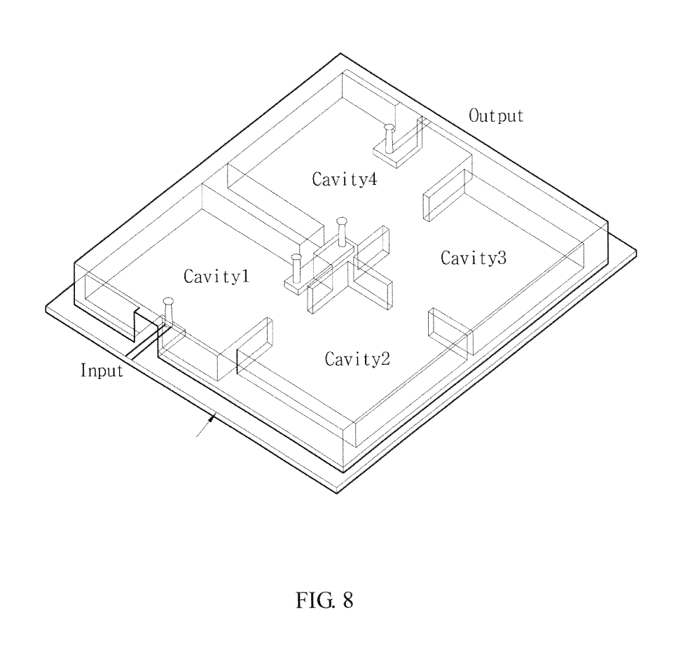

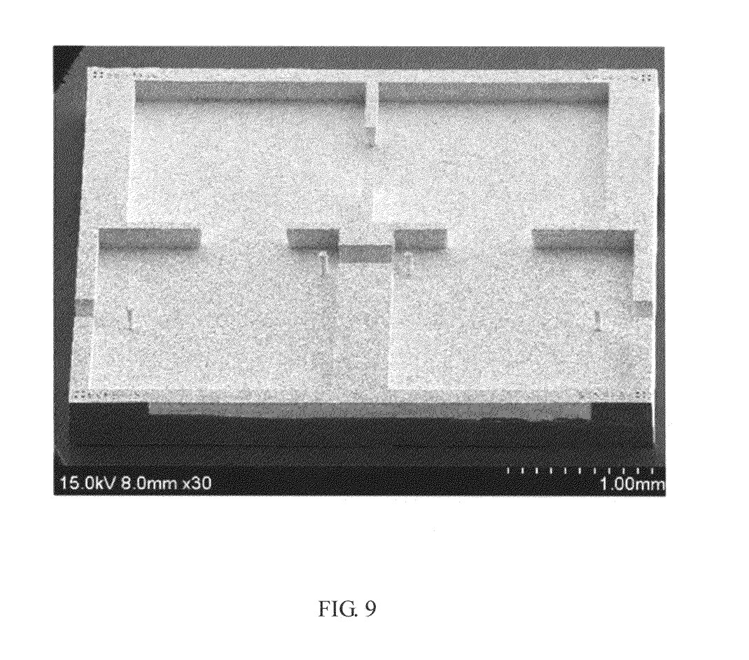

A band-pass filter can be fabricated using the air-cavity resonator of the present invention. FIG. 8 depicts a band-pass filter integrated to the package substrate, and FIG. 9 is an SEM photograph of the band-pass filter air-cavity resonator structure fabricated using the silicon substrate.

High-performance millimeter-wave filters with a low insertion loss and a high degree of selectivity are required in the signal filtering, diplexing, and multiplexing. The band-pass filter of FIGS. 8 and 9 fabricated using the air-cavity resonator can meet those requirements.

A filter with one pair of transmission zeros at finite frequencies can improve the filter selectivity even in the small size with the much improved skirt selectivity.

In general, the cross-coupling between nonadjacent resonators using the positive coupling and the negative coupling brings up the transmission zeros from infinity to finite positions, which provides multiple paths making a signal cancellation between the input and output ports. The positive coupling between the nonadjacent resonators can be easily obtained by a magnetic coupling structure using an inductive iris in the common resonator wall.

However, to generate the negative coupling between the nonadjacent resonators, the process limitation in the air-cavity resonator requires a special attention. A V-band quasi-elliptical band-pass filter can be realized using the negative coupling with the current probe. A four-pole quasi-elliptical band-pass filter is one of the W-band band-pass filters with the lowest insertion loss and the high skirt selectivity.

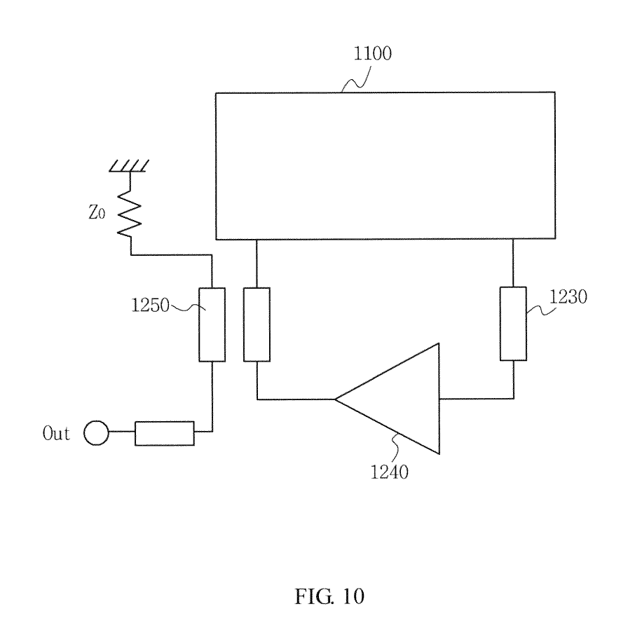

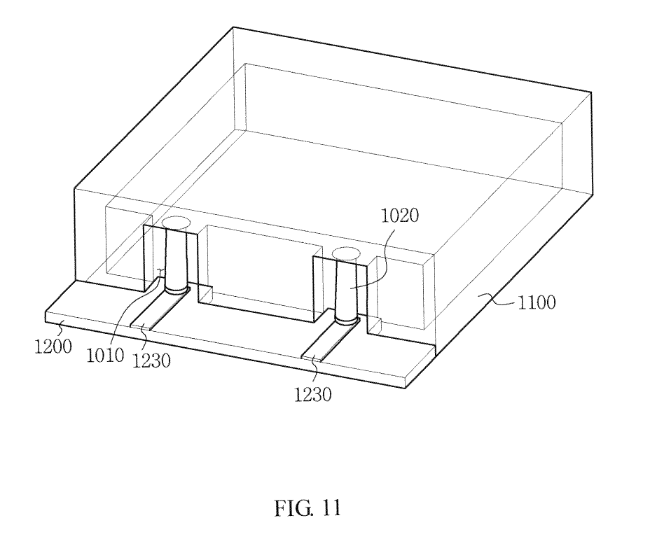

Another application of the air-cavity resonator structure is a V-band CMOS oscillator. FIG. 10 is a circuit diagram of a CMOS oscillator using the air-cavity resonator structure, and FIG. 11 depicts the air-cavity resonator structure applicable to the oscillator structure.

In recent, CMOS technology has emerged as a strong candidate for millimeter-wave applications. However, the CMOS technology encounters challenges due to its inherently poor phase-noise and low-Q factor because a frequency source with low phase-noise and high stability is required for reliable and high quality data transmission in the millimeter-wave applications. To enhance the phase-noise performance of the CMOS frequency source, a high-Q resonator can be employed in a CMOS oscillator circuit because the stability and the phase-noise performance of the oscillator is strongly dependant on the Q factor of the loading circuit.

In the oscillator circuit diagram of FIG. 10, the micromachined air-cavity 1100 is used as a parallel-feedback element of the oscillator, and a Low Noise Amplifier (LNA) using 0.13 μm IBM CMOS technology is used a CMOS gain block 1240 of the parallel-feedback oscillator. One side is connected to the micromachined cavity 1100 through a feeding line 1230, and the other side is connected to an output port through a directional coupler 1250.

As configured above, highly selective positive feedback between the input and the output creates stable oscillations, which is achieved by feeding back part of the output signal into the input through the micromachined air-cavity resonator. Such a configuration enables a relatively straightforward design without concerning spurious oscillations, which can be realized in a series-feedback configuration using the cavity.

In FIG. 11, the micromachined cavity including the I/O ports of the current probe 1020 and the groove structure 1010 in the same side as the air-cavity structure 1100 shortens the length of the feeding lines 1230 coupled with the air-cavity resonator. The micromachined air-cavity resonator is suitable for the parallel-feedback element of FIG. 10.

The oscillator, which is the millimeter-wave oscillator using the silicon technology, can produce the lowest phase-noise performance and the large output power.

So far, the integration method of the micromachined air-cavity with the current probe using the silicon pillars has been described. The silicon pillars, which are formed simultaneously in the deep RIE process for the cavity structure, provide the coupling between the resonator and the external circuit with the minimal package substrate effect. Thus, the micromachined air-cavity can be easily integrated on the package substrate using the flip-chip interconnection.

By virtue of the micromachined cavity, the W-band quasi-elliptical four-pole air-cavity filter and the V-band parallel-feedback CMOS oscillator can be successfully developed on the thin-film substrate with the flip-chip interconnection. This technique can realize low-cost and high-performance millimeter-wave wireless front-end transceivers.

As set forth above, the micromachined air-cavity resonator can be easily manufactured by fabricating a semiconductor substrate such as silicon substrate or GaAs substrate, or a glass substrate, and easily integrated onto a package substrate using flip-chip bonding, metal bonding, and epoxy bonding.

The micromachined air-cavity resonator includes the groove structure which can cancel the detuning effect in the coupling between the external circuit of the package substrate and the current prove, and the current probe simultaneously formed with the air-cavity resonator.

In the micromachined air-cavity resonator, the silicon pillar which is fabricated together with the air-cavity structure through the deep RIE process to form the air-cavity structure can be used as the current probe for coupling the cavity with the external circuit, without additional process for fabricating the current probe.

The novel fabrication method of the air-cavity resonator including metalized silicon pillars is provided.

The millimeter-wave applications of the air-cavity resonator include the cavity filter with the low insertion loss and the oscillator with low phase-noise.

The millimeter-wave wireless front-end module of the low cost and the high efficiency using the air-cavity resonator is provided.

While the invention has been shown and described with reference to certain exemplary embodiments thereof, it will be understood by those skilled in the art that various changes in form and details may be made therein without departing from the spirit and scope of the invention as defined by the appended claims and their equivalents.

What is claimed is:

1. A micromachined air-cavity resonator comprising:
a cavity structure which comprises a current probe simultaneously formed through a fabrication process, and a groove structure; and
a package substrate integrated with the cavity structure.

2. The micromachined air-cavity resonator of claim 1, wherein at least one groove structure is formed to get rid of detuning effect an external circuit and the current probe are interconnected, and at least one current probe is formed in a pillar shape or a wall shape.

3. The micromachined air-cavity resonator of claim 2, wherein an inside of the cavity structure comprising the current prove and the groove structure is metallically plated.

4. The micromachined air-cavity resonator of claim 3, further comprising:
a thin-film microstrip or a Coplanar Waveguide (CPW) for functioning as input and output ports between the cavity structure and the external circuit.

5. The micromachined air-cavity resonator of claim 2, wherein the cavity structure is in the form of a rectangle or a cylinder.

6. The micromachined air-cavity resonator of claim 2, wherein the fabrication process is an etching process on a silicon plate, a GaAs substrate, or a glass substrate.

7. The micromachined air-cavity resonator of claim 2, wherein the cavity structure is integrated onto the package substrate through flip-chip bonding, metal bonding, or epoxy bonding.

8. A band-pass filter coupled with a micromachined air-cavity resonator and integrated to comprise at least one micromachined air-cavity resonator as claimed in claim 1.

9. An oscillator comprising:
a micromachined air-cavity resonator as claimed in claim 1;
a gain block; and
a directional coupler,
wherein the micromachined air-cavity resonator is used as a parallel-feedback element.

10. A fabrication method of a micromachined air-cavity resonator, comprising:
patterning a silicon dioxide film on a silicon substrate;
forming a cavity structure by etching the silicon substrate using the silicon dioxide film as a mask;
metallically plating a surface of the etched silicon substrate; and
mounting the metal plated cavity structure onto the package substrate.

11. The fabrication method of claim 10, wherein the forming of the cavity structure by etching the silicon substrate fabricates the cavity structure to comprise at least one groove structure in a sidewall and at least one silicon pillar current probe within the cavity structure.

12. The fabrication method of claim 11, wherein the mounting of the cavity structure onto the package substrate flip-chip bonds the cavity structure and the package substrate.

13. The fabrication method of claim 12, wherein the etching is carried out using a deep Reactive Ion Etching (RIE) process or a wet-etching process.

14. The fabrication method of claim 10, wherein the silicon dioxide film is deposed in a depth of 2 μm, the silicon substrate is dry-etched with the deep RIE using a Bosch process until a depth of 230 μm is achieved, the metal plating is performed by sputtering Ti/Au seed metal layers and electroplating Au in the depth of 5 μm, and
the mounting of the metal plated cavity structure onto the package substrate is a flip-chip bonding using Au/Sn flip-chip bumps.

15. A band-pass filter fabricated by integrating a micromachined air-cavity resonator fabricated according to the method as claimed in claim 10.

16. An oscillator which employs a micromachined air-cavity resonator fabricated according to the method as claimed in claim 10, as a feedback element.
